(19) United States
(12) Patent Application Publication
(10) Pub. No.: US 2025/0253173 A1
(43) Pub. Date: Aug. 7, 2025

(54) SEMICONDUCTOR MANUFACTURING TOOL AND METHOD OF OPERATING THE SAME

(71) Applicant: TAIWAN SEMICONDUCTOR MANUFACTURING COMPANY LTD., HSINCHU (TW)

(72) Inventors: HONG-JANG WU, PINGTUNG COUNTY (TW); SHIH-LIN JHOU, NEW TAIPEI CITY (TW); YU-JEN CHEN, HSINCHU (TW); PEI-LUN TSAI, HSINCHU CITY (TW)

(21) Appl. No.: 18/433,450

(22) Filed: Feb. 6, 2024

(51) Int. Cl. H01L 21/67; G05B 19/4099; H01L 21/677

(52) U.S. Cl. CPC H01L 21/67184; G05B 19/4099; H01L 21/67739; G05B 2219/45031

(57) ABSTRACT

A semiconductor manufacturing tool and method of operating the same are provided. In one embodiment, the method for manufacturing a semiconductor device comprises: providing the semiconductor device to a load port of a manufacturing tool; detecting a process parameter in a process chamber of the manufacturing tool and control the process parameter to a target range, moving the semiconductor device away from the load port and transferring into the process chamber; and after moving the semiconductor device away from the load port, performing a compensation for the process parameter in the process chamber of the manufacturing tool.

### BACKGROUND

Process control plays a role in semiconductor manufacturing, ensuring efficient and high-quality production. It involves the use of sophisticated algorithms and automation techniques to monitor and optimize various manufacturing processes. By continuously analyzing data from sensors and equipment, it enables real-time adjustments to parameters such as temperature, pressure, and chemical composition. This precision control minimizes variations and defects, leading to improved yield rates and product quality. Additionally, process control enhances productivity by reducing cycle times and increasing throughput. It also enables predictive maintenance, preventing equipment failures and reducing downtime. Overall, it significantly impacts semiconductor production by enhancing efficiency, quality, and reliability.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A, FIG. 1B, FIG. 1C, FIG. 1D and FIG. 1E are schematic illustrations of the operations of the semiconductor manufacturing tool in accordance with an embodiment of the instant disclosure.

FIG. 2A is a flow chart representing a method for operating the semiconductor manufacturing tool in accordance with an embodiment of the present disclosure.

FIG. 2B is a flow chart representing a method for operating the semiconductor manufacturing tool in accordance with an embodiment of the present disclosure.

FIG. 2C is a flow chart representing a method for operating the semiconductor manufacturing tool in accordance with an embodiment of the present disclosure.

FIG. 2D is a flow chart representing a method for operating the semiconductor manufacturing tool in accordance with an embodiment of the present disclosure.

FIG. 3A, FIG. 3B, FIG. 3C, FIG. 3D and FIG. 3E are schematic illustrations of the operations of the semiconductor manufacturing tool in accordance with an embodiment of the instant disclosure.

FIG. 4A is a flow chart representing a method for operating the semiconductor manufacturing tool in accordance with an embodiment of the present disclosure.

FIG. 4B is a flow chart representing a method for operating the semiconductor manufacturing tool in accordance with an embodiment of the present disclosure.

FIG. 4C is a flow chart representing a method for operating the semiconductor manufacturing tool in accordance with an embodiment of the present disclosure.

FIG. 4D is a flow chart representing a method for operating the semiconductor manufacturing tool in accordance with an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

This description of illustrative embodiments is intended to be read in connection with the accompanying drawings, which are to be considered part of the entire written description. In the description of embodiments disclosed herein, any reference to direction or orientation is merely intended for convenience of description and is not intended in any way to limit the scope of the present disclosure. Relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation. Terms such as “attached,” “affixed,” “connected” and “interconnected,” refer to a relationship wherein structures are secured or attached to one another either directly or indirectly through intervening structures, as well as both movable or rigid attachments or relationships, unless expressly described otherwise. Moreover, the features and benefits of the disclosure are illustrated by reference to the embodiments. Accordingly, the disclosure expressly should not be limited to such embodiments illustrating some possible non-limiting combination of features that may exist alone or in other combinations of features; the scope of the disclosure being defined by the claims appended hereto.

Present disclosure provides a semiconductor manufacturing tool, which is configured to provide a compensation for the process parameters in the process chamber during the transfer of the semiconductor device from the load port to the process chamber of the semiconductor manufacturing tool. If the process chamber becomes idle or undergoes alternative processes, leading to a change in its internal environment and a deviation of process parameters from the desired target range, the compensation offered by the semiconductor manufacturing tool can bring the process parameters closer to or within that target range.

Advanced Process Control (APC) may be utilized to detect variations in process parameters within the process chamber and make necessary compensations to ensure process consistency and product quality. When chamber process parameters deviate from set values or expected ranges, APC can undertake the following compensations: 1. Parameter Adjustment: Based on real-time data, APC can automatically adjust the chamber's process parameters, such as temperature, pressure, and gas flow rates, ensuring they return to target ranges; 2. Recipe Change: In some cases, APC might choose a different process recipe to accommodate the detected variations. For instance, it might select a more suitable deposition or etching recipe based on the results from prior wafers or equipment state; 3. Time Alteration: For certain process steps, APC can lengthen or shorten the process time to compensate for parameter variations; 4. Equipment Maintenance Alert: If APC detects persistent or significant variations, it might trigger an alert suggesting equipment maintenance or inspection; 5. Wafer Sorting or Classification: Based on process parameters and the detected data, APC might decide to reclassify certain wafers, for example, segregating them from the prime lot to a secondary lot; and 6. Predictive Maintenance: Through long-term data collection and analysis, APC can predict when equipment might require maintenance or when potential issues might arise, allowing for proactive intervention and minimizing downtime.

A semiconductor manufacturing tool may include a lithography equipment, a dry etching equipment, a chemical vapor deposition (CVD) equipment, a physical vapor deposition (PVD) equipment, an ion implantation equipment, a rapid thermal processing (RTP) equipment, etc. Further, the semiconductor manufacturing tool may include a load port, a load lock and a process chamber. The load port may serve as the entrance to the semiconductor manufacturing tool. It may be designed to receive wafer cassettes (like FOUPs or FOSBs) transferred from automated material handling systems, such as wafer handling robots. That is, the load port may offer an interface where robots can pick or place wafers from or into the cassette. The load lock may act as a transitional area located between the load port and the process chamber. Its primary role is to maintain the vacuum environment inside the semiconductor manufacturing tool while allowing wafers to enter or exit. When wafers move from the non-vacuumed load port to the vacuumed process chamber, they first enter the load lock, where vacuum pumping or venting operations take place. The process chamber may be where the actual process operations (like deposition, etching, etc.) on the wafer occur. It's a sealed environment, typically kept under high vacuum to ensure the precision and repeatability of processes. When a wafer is set to undergo processing, it is initially placed on the load port. The wafer handling robot then extracts the wafer from its cassette and moves it to the load lock. Within the load lock, the wafer is transitioned to the appropriate vacuum level before being moved into the process chamber for processing. Once the processing is complete, the wafer is returned to its cassette via the same path.

Further, an APC (Advanced Process Control) unit may be connected to the semiconductor manufacturing tool. When the semiconductor device, such as the wafer, is transferred to the load port of the semiconductor manufacturing tool, the APC unit may be triggered to detect process parameters in the process chamber, like temperature, pressure, gas flow rates, etc. If the process parameters in the process chamber deviate from the target range, APC unit may make automatic adjustments such that the process parameters in the process chamber reaches the target range. The APC unit is configured to detect the internal environment of the process chamber and adjust the process parameters in the process chamber when the semiconductor device is placed within the load port.

After the APC unit is activated to detect and adjust the internal environment of the process chamber, the semiconductor device may be moved from the load port to the load lock by the atmospheric transfer module (ATM). Further, the semiconductor device may be moved from the load lock to the process chamber by the vacuum transfer module (VTM). After the semiconductor device is moved into the process chamber, a process is performed on it. However, during the above stages, the APC unit is not triggered to monitor or adjust the process parameters within the process chamber. Therefore, if the process chamber becomes idle, other processes are conducted inside it, or for various other reasons, causing the process parameters to deviate from the target range, the semiconductor device may experience failure or a decline in performance.

In some embodiments of the present disclosure, a seasoning process may be performed. The seasoning process may refer to a preparatory setup process ensuring that the conditions within the process chamber are optimal and consistent. Before initiating the actual semiconductor process, such as the stages as above mentioned, the semiconductor manufacturing tool may undergo the seasoning process for a certain duration. This involves subjecting the process chamber to specific routines and conditions, such as heating or pressurizing, to bring the environment within the process chamber to its desired state, priming it for subsequent processes.

However, each seasoning process session takes up time, potentially elongating the overall production cycle. Further, as the seasoning process might use up energy or other materials without directly contributing to product fabrication, there might be some wastage. Moreover, frequent seasoning might lead to quicker wear and tear of the equipment, affecting its lifespan.

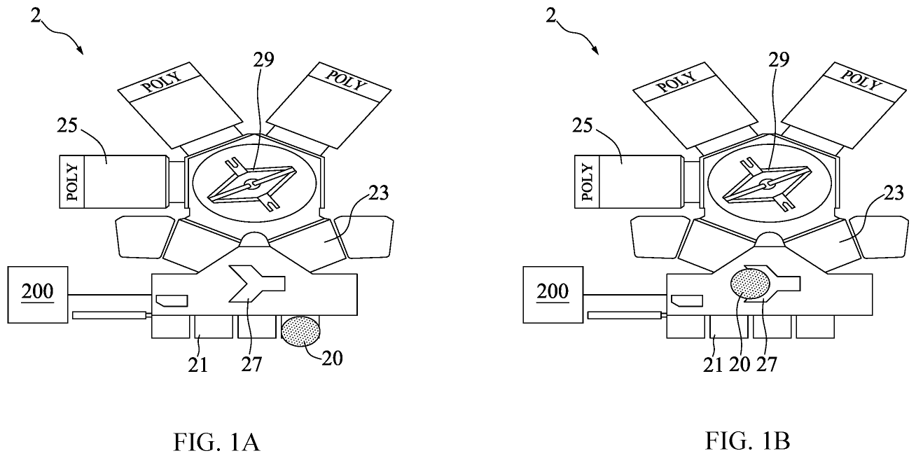

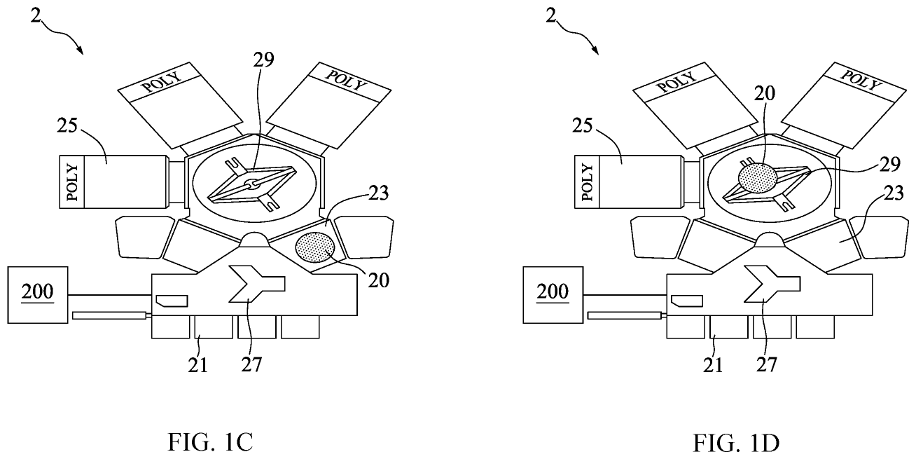

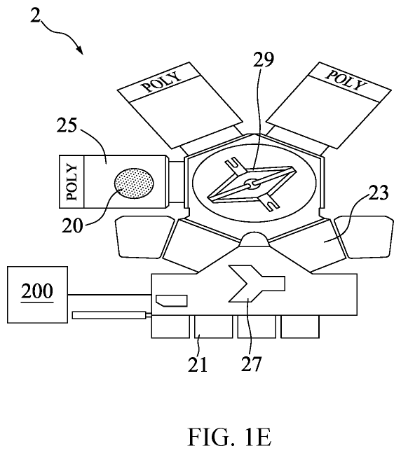

FIG. 1A, FIG. 1B, FIG. 1C, FIG. 1D and FIG. 1E are schematic illustrations of the operations of the semiconductor manufacturing tool 2 in accordance with an embodiment of the instant disclosure. In some embodiments of the present disclosure, the semiconductor manufacturing tool 2 may include a lithography equipment, a dry etching equipment, a chemical vapor deposition (CVD) equipment, a physical vapor deposition (PVD) equipment, an ion implantation equipment, a rapid thermal processing (RTP) equipment, etc. As shown in FIG. 1A, FIG. 1B, FIG. 1C, FIG. 1D and FIG. 1E, the semiconductor manufacturing tool 2 may include a load port 21, a load lock 23 and a process chamber 25. The load port 21 may serve as the entrance to the semiconductor manufacturing tool 2. It's designed to receive wafer cassettes (like FOUPs or FOSBs) transferred from automated material handling systems, such as wafer handling robots. That is, the load port 21 may offer an interface where robots can pick or place wafers from or into the cassette. The load lock 23 may act as a transitional area located between the load port 21 and the process chamber 25. Its primary role is to maintain the vacuum environment inside the semiconductor manufacturing tool 2 while allowing wafers to enter or exit. When wafers move from the non-vacuumed load port 21 to the vacuumed process chamber 25, they first enter the load lock 23, where vacuum pumping or venting operations take place. The process chamber 25 may be where the actual process operations (like deposition, etching, etc.) on the wafer occur. It's a sealed environment, typically kept under high vacuum to ensure the precision and repeatability of processes. When a wafer is set to undergo processing, it is initially placed on the load port 21. The wafer handling robot then extracts the wafer from its cassette and moves it to the load lock 23. Within the load lock 23, the wafer is transitioned to the appropriate vacuum level before being moved into the process chamber 25 for processing. Once the processing is complete, the wafer is returned to its cassette via the same path.

Further, an APC (Advanced Process Control) unit 200 may be connected to the semiconductor manufacturing tool 2. As shown in FIG. 1A, when the semiconductor device 20, such as the wafer, is transferred to the load port 21 of the semiconductor manufacturing tool 2, the APC unit 200 may be triggered to detect process parameters in the process chamber 25, like temperature, pressure, gas flow rates, etc. If the process parameters in the process chamber 25 deviate from the target range, APC unit 200 may make automatic adjustments such that the process parameters in the process chamber 25 reaches the target range. That is, APC unit 200 may deal with more massive and complex calculations and all APC defense checking. After the calculations and defense checking, APC unit 200 may adjust the process parameters in the process chamber 25 to reach the target range.

Referring to FIG. 1B, the semiconductor device 20 may be moved from the load port 21 to the load lock 23. In some embodiments of the present disclosure, an atmospheric transfer module (ATM) 27 of the semiconductor manufacturing tool 2 may pick the semiconductor device 20 from the load port 21 and transfers the semiconductor device 20 to the load lock 23. The APC 200 may be triggered to monitor and adjust the process parameters in the process chamber 25 at this stage. If the process chamber 25 becomes idle, or other processes are conducted inside the process chamber 25, such as dry clean seasoning, or for various other reasons, causing the process parameters in the process chamber 25 to deviate from the target range, the APC unit 200 will detect these deviations and will adjust the process parameters within the process chamber 25 in real-time. That is, once the APC unit 200 finds that the process parameters in the process chamber 25 deviates from the target range, the APC unit 200 may control the semiconductor manufacturing tool 2 and provide a compensation such that the process parameters in the process chamber 25 to be back to the target range. Otherwise, if the APC unit 200 finds that the process parameters in the process chamber 25 is still in the target range, the APC unit 200 may not provide the compensation to adjust the process parameters in the process chamber 25. That is, the decision on whether the APC unit 200 needs to provide compensation and how to provide it is determined by the target range calculated by the initial APC unit 200 and the internal environment of the process chamber 25 detected by the APC unit 200 during the later stage. In other words, the compensation may be provided based on the detection obtained by the APC unit 100 when the semiconductor device 20 is in the load port 21 and the detection obtained by the APC unit when the semiconductor device 20 is moved by the atmospheric transfer module (ATM) 27.

Referring to FIG. 1C, the semiconductor device 20 may be moved into the load lock 23. In some embodiments of the present disclosure, the semiconductor device 20 may be transferred in to the load lock 23 by the atmospheric transfer module (ATM) 27 of the semiconductor manufacturing tool 2. The APC 200 may be triggered to monitor and adjust the process parameters in the process chamber 25 at this stage. If the process chamber 25 becomes idle, or other processes are conducted inside the process chamber 25, such as dry clean seasoning, or for various other reasons, causing the process parameters in the process chamber 25 to deviate from the target range, the APC unit 200 will detect these deviations and will adjust the process parameters within the process chamber 25 in real-time. That is, once the APC unit 200 finds that the process parameters in the process chamber 25 deviates from the target range, the APC unit 200 may control the semiconductor manufacturing tool 2 and provide a compensation such that the process parameters in the process chamber 25 to be back to the target range. Otherwise, if the APC unit 200 finds that the process parameters in the process chamber 25 is still in the target range, the APC unit 200 may not provide the compensation to adjust the process parameters in the process chamber 25. That is, the decision on whether the APC unit 200 needs to provide compensation and how to provide it is determined by the target range calculated by the initial APC unit 200 and the internal environment of the process chamber 25 detected by the APC unit 200 during the later stage. In other words, the compensation may be provided based on the detection obtained by the APC unit 100 when the semiconductor device 20 is in the load port 21 and the detection obtained by the APC unit when the semiconductor device 20 is transferred in to the load lock 23.

Referring to FIG. 1D, the semiconductor device 20 may be moved from the load lock 23 to the process chamber 25. In some embodiments of the present disclosure, a vacuum transfer module (VTM) 29 of the semiconductor manufacturing tool 2 may pick the semiconductor device 20 from the load lock 23 and transfers the semiconductor device 20 to the process chamber 25. The APC 200 may be triggered to monitor and adjust the process parameters in the process chamber 25 at this stage. If the process chamber 25 becomes idle, or other processes are conducted inside the process chamber 25, such as dry clean seasoning, or for various other reasons, causing the process parameters in the process chamber 25 to deviate from the target range, the APC unit 200 will detect these deviations and will adjust the process parameters within the process chamber 25 in real-time. That is, once the APC unit 200 finds that the process parameters in the process chamber 25 deviates from the target range, the APC unit 200 may control the semiconductor manufacturing tool 2 and provide a compensation such that the process parameters in the process chamber 25 to be back to the target range. Otherwise, if the APC unit 200 finds that the process parameters in the process chamber 25 is still in the target range, the APC unit 200 may not provide the compensation to adjust the process parameters in the process chamber 25. That is, the decision on whether the APC unit 200 needs to provide compensation and how to provide it is determined by the target range calculated by the initial APC unit 200 and the internal environment of the process chamber 25 detected by the APC unit 200 during the later stage. In other words, the compensation may be provided based on the detection obtained by the APC unit 100 when the semiconductor device 20 is in the load port 21 and the detection obtained by the APC unit when the semiconductor device 20 is moved by vacuum transfer module (VTM) 29.

Referring to FIG. 1E, the semiconductor device 20 may be moved into the process chamber 25. In some embodiments of the present disclosure, the semiconductor device 20 may be transferred in to the process chamber 25 by the vacuum transfer module (VTM) 29 of the semiconductor manufacturing tool 2. The APC 200 may be triggered to monitor and adjust the process parameters in the process chamber 25 at this stage. If the process chamber 25 becomes idle, or other processes are conducted inside the process chamber 25, such as dry clean seasoning, or for various other reasons, causing the process parameters in the process chamber 25 to deviate from the target range, the APC unit 200 will detect these deviations and will adjust the process parameters within the process chamber 25 in real-time. That is, once the APC unit 200 finds that the process parameters in the process chamber 25 deviates from the target range, the APC unit 200 may control the semiconductor manufacturing tool 2 and provide a compensation such that the process parameters in the process chamber 25 to be back to the target range. Otherwise, if the APC unit 200 finds that the process parameters in the process chamber 25 is still in the target range, the APC unit 200 may not provide the compensation to adjust the process parameters in the process chamber 25. That is, the decision on whether the APC unit 200 needs to provide compensation and how to provide it is determined by the target range calculated by the initial APC unit 200 and the internal environment of the process chamber 25 detected by the APC unit 200 during the later stage. In other words, the compensation may be provided based on the detection obtained by the APC unit 100 when the semiconductor device 20 is in the load port 21 and the detection obtained by the APC unit when the semiconductor device 20 transferred in to the process chamber 25.

After the semiconductor device 20 is moved into the process chamber 25, the semiconductor manufacturing tool 2 may perform a process on the semiconductor device 20. As above mentioned, the APC unit 200 may be triggered to monitor or adjust the process parameters within the process chamber 25 during the stages illustrated in FIG. 1B through FIG. 1E. Therefore, the process parameters in the process chamber 25 may be maintained in the target region even if the process chamber 25 becomes idle, or other processes are conducted inside the process chamber, such as dry clean seasoning, or for various other reasons, that may cause the process parameters in the process chamber 25 to deviate from the target range. That is, the semiconductor manufacturing tool 2 may ensure high-quality, efficient, and consistent production.

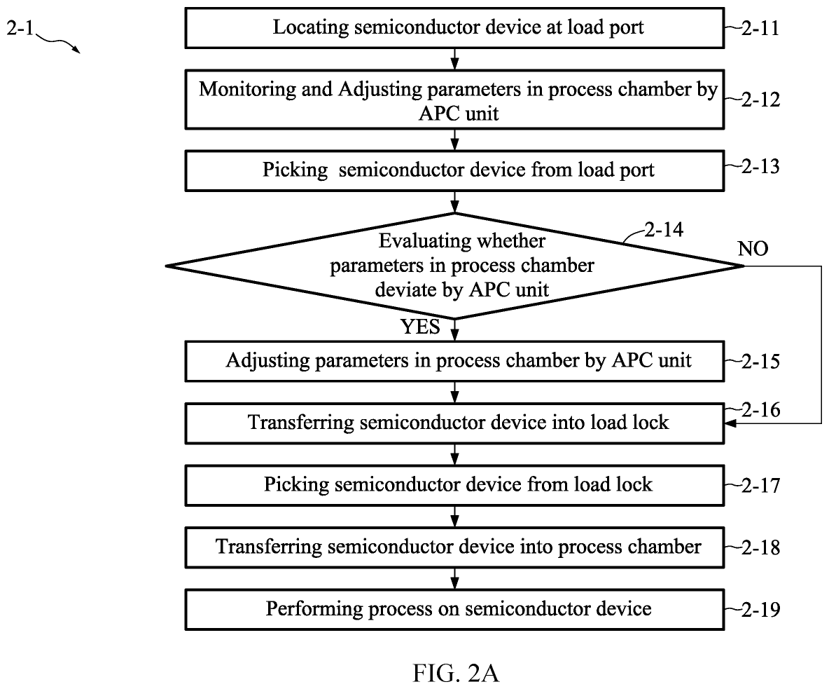

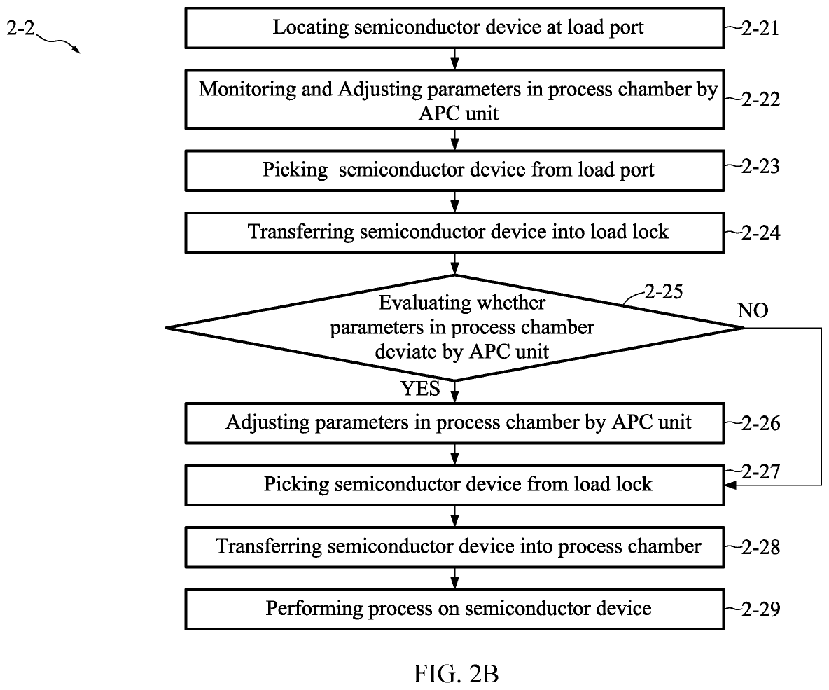

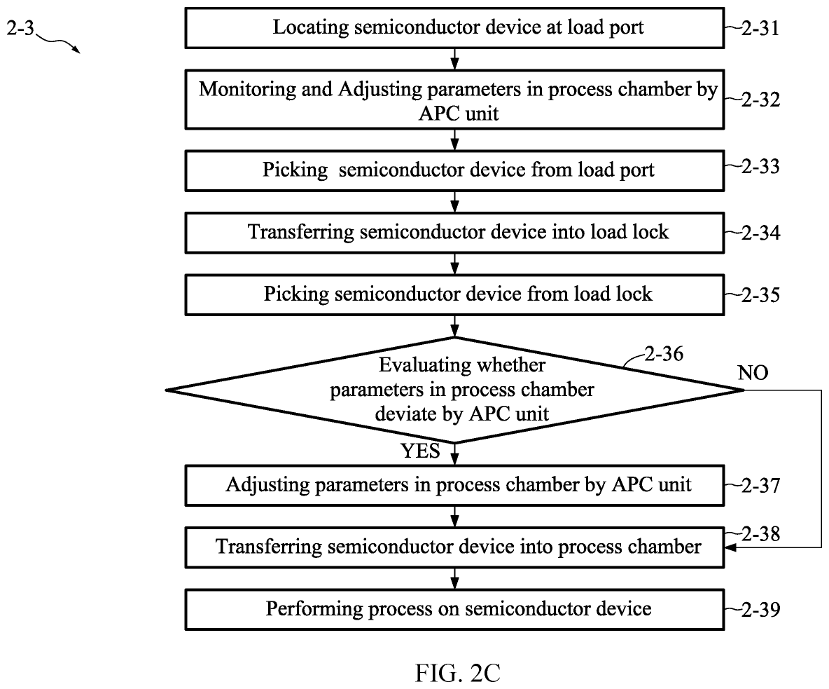

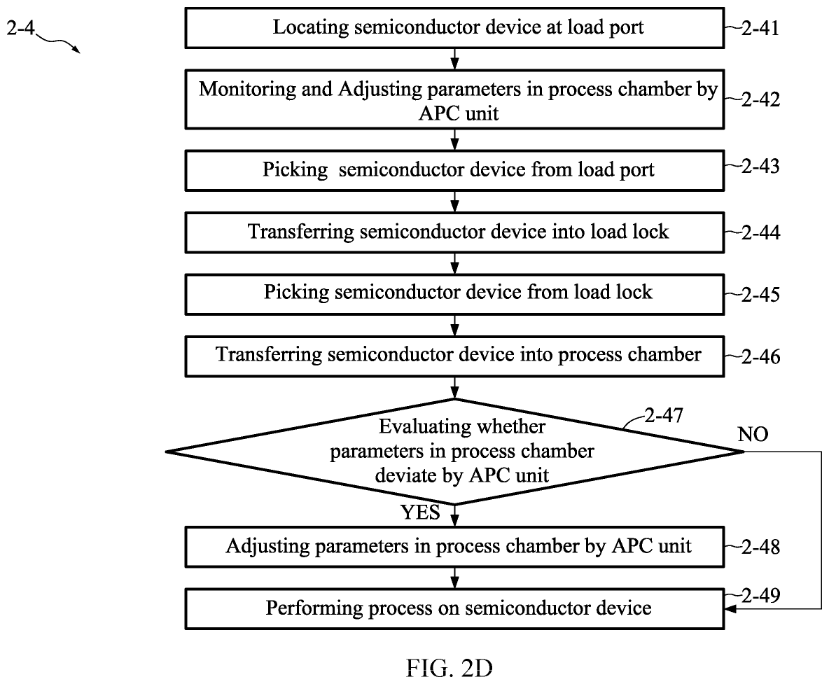

FIG. 2A is a flow chart representing a method 2-1 for operating the semiconductor manufacturing tool 2 in accordance with an embodiment of the present disclosure.

In operation 2-11, the semiconductor device 20 may be placed at the load port 21 of the semiconductor manufacturing tool 2. In some embodiments of the present disclosure, the semiconductor device 20 may be transferred from automated material handling systems, such as wafer handling robots.

In operation 2-12, the APC unit 200 may be triggered to monitor the process parameters in the process chamber 25. If the APC unit 200 detects that the process parameters in the process chamber 25 deviate from the target range, the APC unit 200 may make automatic adjustments such that the process parameters in the process chamber 25 reaches the target range.

In operation 2-13, the semiconductor device 20 may be picked from the load port 21 and be transferred to the load lock 23. In some embodiments of the present disclosure, the atmospheric transfer module (ATM) 27 of the semiconductor manufacturing tool 2 may pick the semiconductor device 20 from the load port 21 and transfers the semiconductor device 20 to the load lock 23.

In operation 2-14, during the movement of the semiconductor device 20, the APC unit 200 may be triggered to monitor the process parameters in the process chamber 25 and determine whether the process parameters in the process chamber 25 deviate from the target range. If, during or before this period, the process chamber 25 is left idle or undergoes other processes, the process parameters in the process chamber 25 may deviate from the target range. The APC unit 200 may detect such deviations.

In operation 2-15, if the APC unit 200 detects that the process parameters in the process chamber 25 deviates from the target range, the APC unit 200 may provide a compensation so as to adjust the process parameters in the process chamber 25 to be back in the target range. Otherwise, if the APC unit 200 detects that the process parameters in the process chamber 25 is still in the target range, the APC unit 200 may not adjust the process parameters in the process chamber 25 and the semiconductor manufacturing tool 2 may directly perform operation 2-16.

In operation 2-16, the semiconductor device 20 may be moved into the load lock 23 of the semiconductor manufacturing tool 2.

In operation 2-17, the semiconductor device 20 may be picked from the load lock 23 and be transferred to the process chamber 25. In some embodiments of the present disclosure, the vacuum transfer module (VTM) 29 of the semiconductor manufacturing tool 2 may pick the semiconductor device 20 from the load lock 23 and transfers the semiconductor device 20 to the process chamber 25.

In operation 2-18, the semiconductor device 20 may be moved into the process chamber 25 of the semiconductor manufacturing tool 2.

In operation 2-19, after the semiconductor device 20 is moved into the process chamber 25, the semiconductor manufacturing tool 2 may perform the semiconductor manufacturing process on the semiconductor device 20.

FIG. 2B is a flow chart representing a method 2-2 for operating the semiconductor manufacturing tool 2 in accordance with an embodiment of the present disclosure.

In operation 2-21, the semiconductor device 20 may be placed at the load port 21 of the semiconductor manufacturing tool 2. In some embodiments of the present disclosure, the semiconductor device 20 may be transferred from automated material handling systems, such as wafer handling robots.

In operation 2-22, the APC unit 200 may be triggered to monitor the process parameters in the process chamber 25. If the APC unit 200 detects that the process parameters in the process chamber 25 deviate from the target range, the APC unit 200 may make automatic adjustments such that the process parameters in the process chamber 25 reaches the target range.

In operation 2-23, the semiconductor device 20 may be picked from the load port 21 and be transferred to the load lock 23. In some embodiments of the present disclosure, the atmospheric transfer module (ATM) 27 of the semiconductor manufacturing tool 2 may pick the semiconductor device 20 from the load port 21 and transfers the semiconductor device 20 to the load lock 23.

In operation 2-24, the semiconductor device 20 may be moved into the load lock 23 of the semiconductor manufacturing tool 2.

In operation 2-25, after moving the semiconductor device 20 into the load lock 22, the APC unit 200 may be triggered to monitor the process parameters in the process chamber 25 and determine whether the process parameters in the process chamber 25 deviate from the target range. If, during or before this stage, the process chamber 25 is left idle or undergoes other processes, the process parameters in the process chamber 25 may deviate from the target range. The APC unit 200 may detect such deviations.

In operation 2-26, if the APC unit 200 detects that the process parameters in the process chamber 25 deviates from the target range, the APC unit 200 may provide a compensation so as to adjust the process parameters in the process chamber 25 to be back in the target range. Otherwise, if the APC unit 200 detects that the process parameters in the process chamber 25 is still in the target range, the APC unit 200 may not adjust the process parameters in the process chamber 25 and the semiconductor manufacturing tool 2 may directly perform operation 2-27.

In operation 2-27, the semiconductor device 20 may be picked from the load lock 23 and be transferred to the process chamber 25. In some embodiments of the present disclosure, the vacuum transfer module (VTM) 29 of the semiconductor manufacturing tool 2 may pick the semiconductor device 20 from the load lock 23 and transfers the semiconductor device 20 to the process chamber 25.

In operation 2-28, the semiconductor device 20 may be moved into the process chamber 25 of the semiconductor manufacturing tool 2.

In operation 2-29, after the semiconductor device 20 is moved into the process chamber 25, the semiconductor manufacturing tool 2 may perform the semiconductor manufacturing process on the semiconductor device 20.

FIG. 2C is a flow chart representing a method 2-3 for operating the semiconductor manufacturing tool 2 in accordance with an embodiment of the present disclosure.

In operation 2-31, the semiconductor device 20 may be placed at the load port 21 of the semiconductor manufacturing tool 2. In some embodiments of the present disclosure, the semiconductor device 20 may be transferred from automated material handling systems, such as wafer handling robots.

In operation 2-32, the APC unit 200 may be triggered to monitor the process parameters in the process chamber 25. If the APC unit 200 detects that the process parameters in the process chamber 25 deviate from the target range, the APC unit 200 may make automatic adjustments such that the process parameters in the process chamber 25 reaches the target range.

In operation 2-33, the semiconductor device 20 may be picked from the load port 21 and be transferred to the load lock 23. In some embodiments of the present disclosure, the atmospheric transfer module (ATM) 27 of the semiconductor manufacturing tool 2 may pick the semiconductor device 20 from the load port 21 and transfers the semiconductor device 20 to the load lock 23.

In operation 2-34, the semiconductor device 20 may be moved into the load lock 23 of the semiconductor manufacturing tool 2.

In operation 2-35, the semiconductor device 20 may be picked from the load lock 23 and be transferred to the process chamber 25. In some embodiments of the present disclosure, the vacuum transfer module (VTM) 29 of the semiconductor manufacturing tool 2 may pick the semiconductor device 20 from the load lock 23 and transfers the semiconductor device 20 to the process chamber 25.

In operation 2-36, during the movement of the semiconductor device 20, the APC unit 200 may be triggered to monitor the process parameters in the process chamber 25 and determine whether the process parameters in the process chamber 25 deviate from the target range. If, during or before this period, the process chamber 25 is left idle or undergoes other processes, the process parameters in the process chamber 25 may deviate from the target range. The APC unit 200 may detect such deviations.

In operation 2-37, if the APC unit 200 detects that the process parameters in the process chamber 25 deviates from the target range, the APC unit 200 may provide a compensation so as to adjust the process parameters in the process chamber 25 to be back in the target range. Otherwise, if the APC unit 200 detects that the process parameters in the process chamber 25 is still in the target range, the APC unit 200 may not adjust the process parameters in the process chamber 25 and the semiconductor manufacturing tool 2 may directly perform operation 2-38.

In operation 2-38, the semiconductor device 20 may be moved into the process chamber 25 of the semiconductor manufacturing tool 2.

In operation 2-39, after the semiconductor device 20 is moved into the process chamber 25, the semiconductor manufacturing tool 2 may perform the semiconductor manufacturing process on the semiconductor device 20.

FIG. 2D is a flow chart representing a method 2-4 for operating the semiconductor manufacturing tool 2 in accordance with an embodiment of the present disclosure.

In operation 2-41, the semiconductor device 20 may be placed at the load port 21 of the semiconductor manufacturing tool 2. In some embodiments of the present disclosure, the semiconductor device 20 may be transferred from automated material handling systems, such as wafer handling robots.

In operation 2-42, the APC unit 200 may be triggered to monitor the process parameters in the process chamber 25. If the APC unit 200 detects that the process parameters in the process chamber 25 deviate from the target range, the APC unit 200 may make automatic adjustments such that the process parameters in the process chamber 25 reaches the target range.

In operation 2-43, the semiconductor device 20 may be picked from the load port 21 and be transferred to the load lock 23. In some embodiments of the present disclosure, the atmospheric transfer module (ATM) 27 of the semiconductor manufacturing tool 2 may pick the semiconductor device 20 from the load port 21 and transfers the semiconductor device 20 to the load lock 23.

In operation 2-44, the semiconductor device 20 may be moved into the load lock 23 of the semiconductor manufacturing tool 2.

In operation 2-45, the semiconductor device 20 may be picked from the load lock 23 and be transferred to the process chamber 25. In some embodiments of the present disclosure, the vacuum transfer module (VTM) 29 of the semiconductor manufacturing tool 2 may pick the semiconductor device 20 from the load lock 23 and transfers the semiconductor device 20 to the process chamber 25.

In operation 2-46, the semiconductor device 20 may be moved into the process chamber 25 of the semiconductor manufacturing tool 2.

In operation 2-47, after moving the semiconductor device 20 into the process chamber 25, the APC unit 200 may be triggered to monitor the process parameters in the process chamber 25 and determine whether the process parameters in the process chamber 25 deviate from the target range. If, during or before this stage, the process chamber 25 is left idle or undergoes other processes, the process parameters in the process chamber 25 may deviate from the target range. The APC unit 200 may detect such deviations.

In operation 2-48, if the APC unit 200 detects that the process parameters in the process chamber 25 deviates from the target range, the APC unit 200 may provide a compensation so as to adjust the process parameters in the process chamber 25 to be back in the target range. Otherwise, if the APC unit 200 detects that the process parameters in the process chamber 25 is still in the target range, the APC unit 200 may not adjust the process parameters in the process chamber 25 and the semiconductor manufacturing tool 2 may directly perform operation 2-49.

In operation 2-49, after the semiconductor device 20 is moved into the process chamber 25, the semiconductor manufacturing tool 2 may perform the semiconductor manufacturing process on the semiconductor device 20.

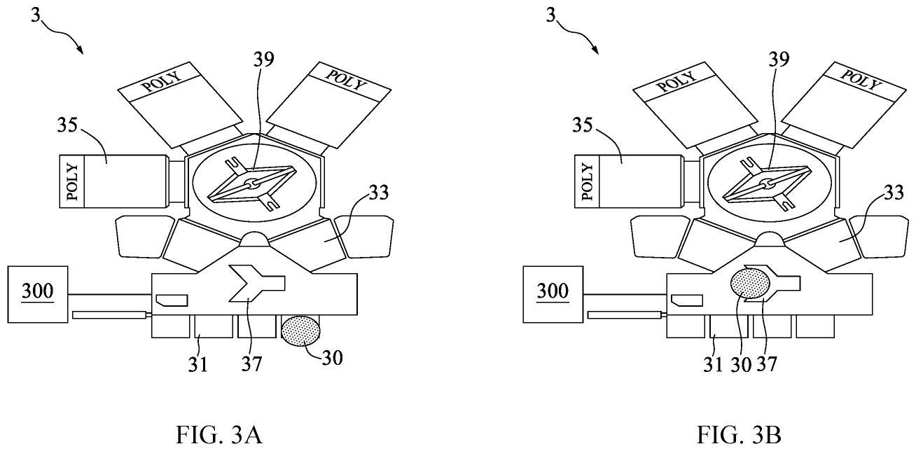

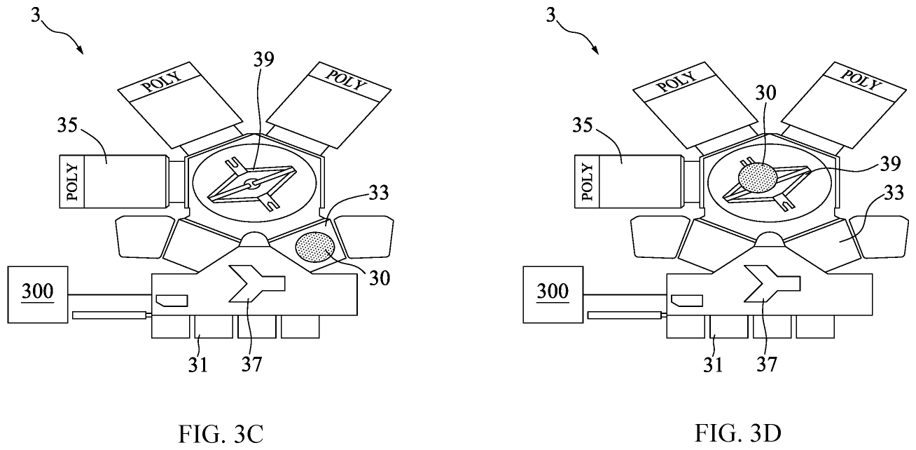

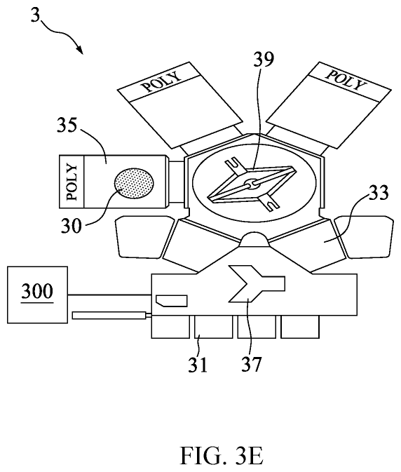

FIG. 3A, FIG. 3B, FIG. 3C, FIG. 3D and FIG. 3E are schematic illustrations of the operations of the semiconductor manufacturing tool 3 in accordance with an embodiment of the instant disclosure. In some embodiments of the present disclosure, the semiconductor manufacturing tool 3 may include a lithography equipment, a dry etching equipment, a chemical vapor deposition (CVD) equipment, a physical vapor deposition (PVD) equipment, an ion implantation equipment, a rapid thermal processing (RTP) equipment, etc. As shown in FIG. 3A, FIG. 3B, FIG. 3C, FIG. 3D and FIG. 3E, the semiconductor manufacturing tool 3 may include a load port 31, a load lock 33 and a process chamber 35. The load port 31 may serve as the entrance to the semiconductor manufacturing tool 3. It's designed to receive wafer cassettes (like FOUPs or FOSBs) transferred from automated material handling systems, such as wafer handling robots. That is, the load port 31 may offer an interface where robots can pick or place wafers from or into the cassette. The load lock 33 may act as a transitional area located between the load port 31 and the process chamber 35. Its primary role is to maintain the vacuum environment inside the semiconductor manufacturing tool 3 while allowing wafers to enter or exit. When wafers move from the non-vacuumed load port 31 to the vacuumed process chamber 35, they first enter the load lock 33, where vacuum pumping or venting operations take place. The process chamber 35 may be where the actual process operations (like deposition, etching, etc.) on the wafer occur. It's a sealed environment, typically kept under high vacuum to ensure the precision and repeatability of processes. When a wafer is set to undergo processing, it is initially placed on the load port 31. The wafer handling robot then extracts the wafer from its cassette and moves it to the load lock 33. Within the load lock 33, the wafer is transitioned to the appropriate vacuum level before being moved into the process chamber 35 for processing. Once the processing is complete, the wafer is returned to its cassette via the same path.

Further, an APC (Advanced Process Control) unit 300 may be connected to the semiconductor manufacturing tool 3. As shown in FIG. 3A, when the semiconductor device 30, such as the wafer, is transferred to the load port 31 of the semiconductor manufacturing tool 3, the APC unit 300 may be triggered to detect process parameters in the process chamber 35, like temperature, pressure, gas flow rates, etc. If the process parameters in the process chamber 35 deviate from the target range, APC unit 300 may make automatic adjustments such that the process parameters in the process chamber 35 reaches the target range.

Referring to FIG. 3B, the semiconductor device 30 may be moved from the load port 31 to the load lock 33. In some embodiments of the present disclosure, an atmospheric transfer module (ATM) 37 of the semiconductor manufacturing tool 3 may pick the semiconductor device 30 from the load port 31 and transfers the semiconductor device 30 to the load lock 33. In some embodiments of the present disclosure, the semiconductor manufacturing tool 3 may include a program 301, which is configured to drive the semiconductor manufacturing tool 3 to provide a compensation for the process parameter in the process chamber 35. In some embodiments of the present disclosure, the program 301 may be embedded within the processor of the semiconductor manufacturing tool 3. In some embodiments of the present disclosure, the program 301 may automatically drive the semiconductor manufacturing tool 3 to provide a compensation for the process parameter in the process chamber 35 when the atmospheric transfer module (ATM) 37 of the semiconductor manufacturing tool 3 moves the semiconductor device 30 from the load port 31 to the load lock 33. That is, the provision of the compensation is programmable. Further, such compensation may be predetermined and constant. In other words, the compensation can be pre-set in the semiconductor tool and can be predetermined as a constant. The compensation is provided with different settings based on different semiconductor processes and/or different semiconductor tools. If the process chamber 35 becomes idle, or other processes are conducted inside the process chamber 35, such as dry clean seasoning, or for various other reasons, causing the process parameters in the process chamber 35 to deviate from the target range, the compensation driven by the program 301 may cause the process parameters in the process chamber 35 approaches the target range.

Referring to FIG. 3C, the semiconductor device 30 may be moved into the load lock 33. In some embodiments of the present disclosure, the semiconductor device 30 may be transferred in to the load lock 33 by the atmospheric transfer module (ATM) 37 of the semiconductor manufacturing tool 3. In some embodiments of the present disclosure, the program 301 may automatically drive the semiconductor manufacturing tool 3 to provide the compensation for the process parameter in the process chamber 35 at this stage. If the process chamber 35 becomes idle, or other processes are conducted inside the process chamber 35, such as dry clean seasoning, or for various other reasons, causing the process parameters in the process chamber 35 to deviate from the target range, the compensation driven by the program 301 may cause the process parameters in the process chamber 35 approaches the target range.

Referring to FIG. 3D, the semiconductor device 30 may be moved from the load lock 33 to the process chamber 35. In some embodiments of the present disclosure, a vacuum transfer module (VTM) 39 of the semiconductor manufacturing tool 3 may pick the semiconductor device 30 from the load lock 33 and transfers the semiconductor device 30 to the process chamber 35. In some embodiments of the present disclosure, the program 301 may automatically drive the semiconductor manufacturing tool 3 to provide the compensation for the process parameter in the process chamber 35 at this stage. If the process chamber 35 becomes idle, or other processes are conducted inside the process chamber 35, such as dry clean seasoning, or for various other reasons, causing the process parameters in the process chamber 35 to deviate from the target range, the compensation driven by the program 301 may cause the process parameters in the process chamber 35 approaches the target range.

Referring to FIG. 3E, the semiconductor device 30 may be moved into the process chamber 35. In some embodiments of the present disclosure, the semiconductor device 30 may be transferred in to the process chamber 35 by the vacuum transfer module (VTM) 39 of the semiconductor manufacturing tool 3. In some embodiments of the present disclosure, the program 301 may automatically drive the semiconductor manufacturing tool 3 to provide the compensation for the process parameter in the process chamber 35 at this stage. If the process chamber 35 becomes idle, or other processes are conducted inside the process chamber 35, such as dry clean seasoning, or for various other reasons, causing the process parameters in the process chamber 35 to deviate from the target range, the compensation driven by the program 301 may cause the process parameters in the process chamber 35 approaches the target range.

After the semiconductor device 30 is moved into the process chamber 35, the semiconductor manufacturing tool 3 may perform a process on the semiconductor device 30. As above mentioned, the program 301 in the semiconductor manufacturing tool 3 may drive the semiconductor manufacturing tool 3 to provide the compensation for the process parameters within the process chamber 35 during the stages illustrated in FIG. 3B through FIG. 3E. Therefore, the process parameters in the process chamber 35 may be close to the target region even if the process chamber 35 becomes idle, or other processes are conducted inside the process chamber, such as dry clean seasoning, or for various other reasons, that may cause the process parameters in the process chamber 35 to deviate from the target range. That is, the semiconductor manufacturing tool 3 may ensure high-quality, efficient, and consistent production.

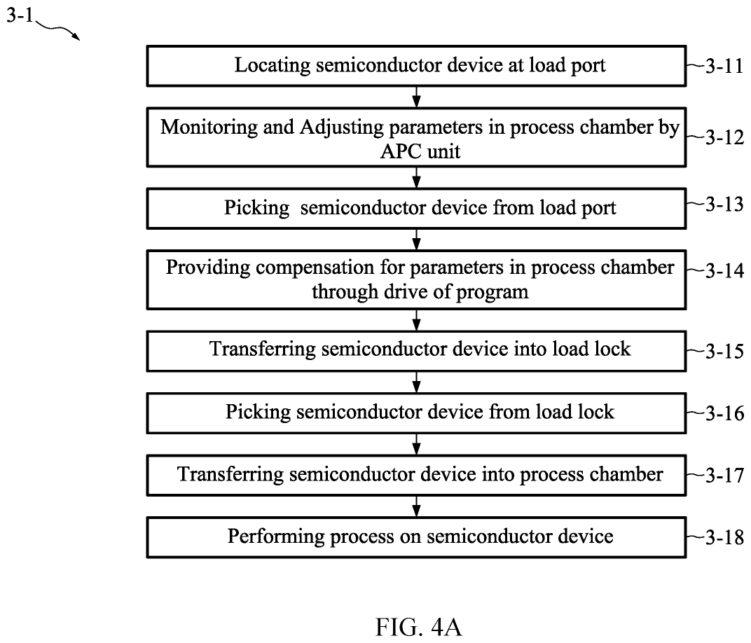

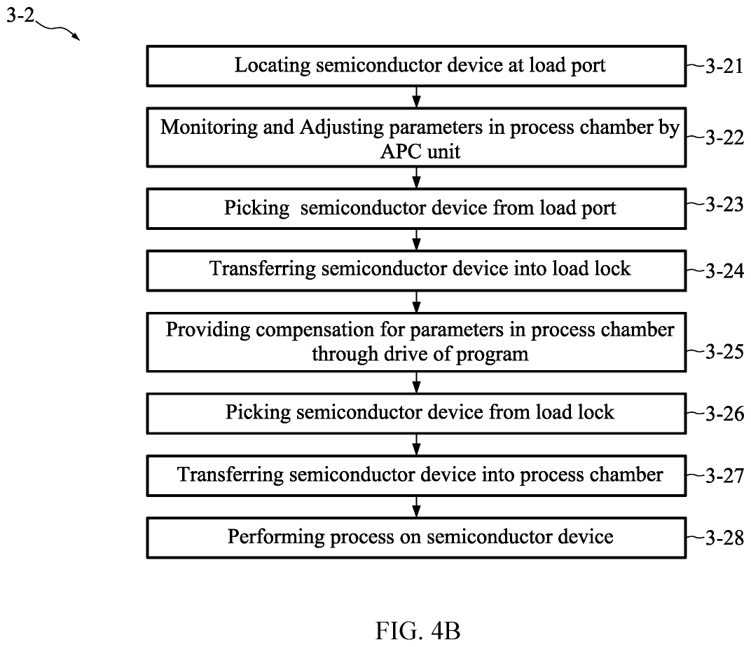

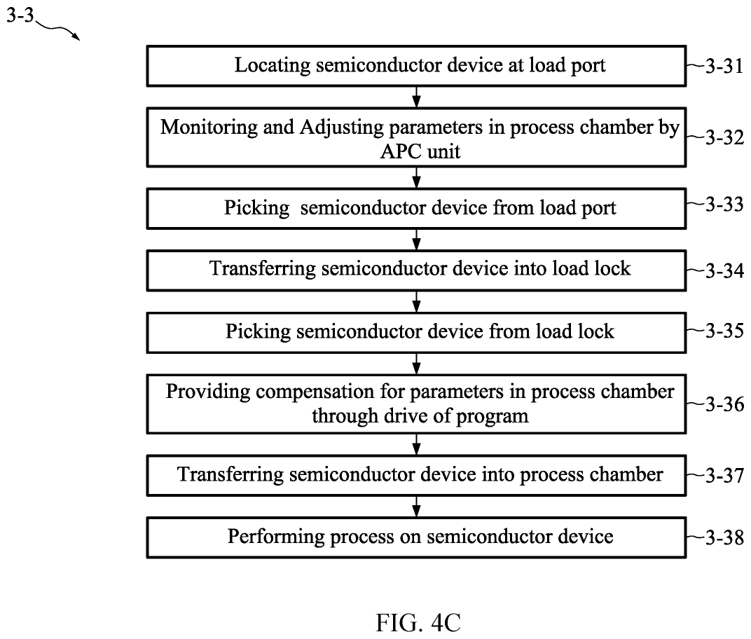

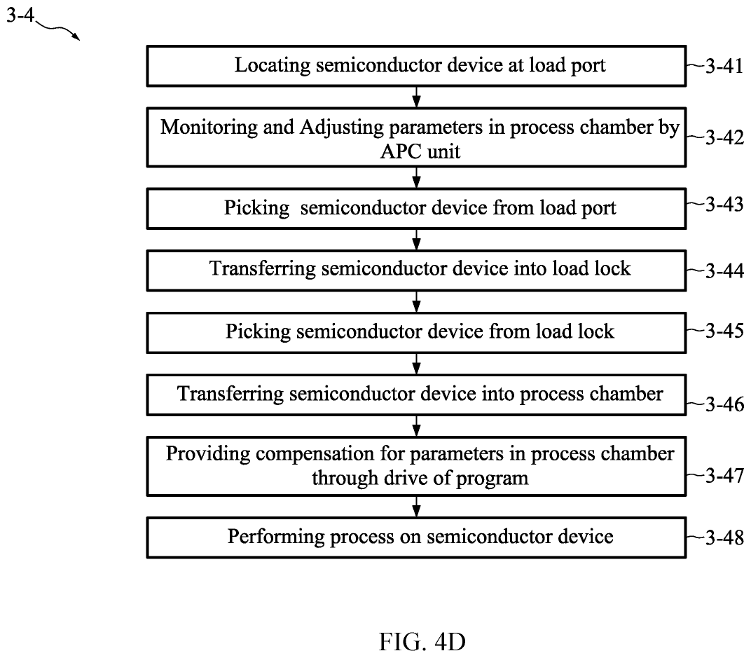

FIG. 4A is a flow chart representing a method 3-1 for operating the semiconductor manufacturing tool 3 in accordance with an embodiment of the present disclosure.

In operation 3-11, the semiconductor device 30 may be placed at the load port 31 of the semiconductor manufacturing tool 3. In some embodiments of the present disclosure, the semiconductor device 30 may be transferred from automated material handling systems, such as wafer handling robots.

In operation 3-12, the APC unit 300 may be triggered to monitor the process parameters in the process chamber 35. If the APC unit 300 detects that the process parameters in the process chamber 35 deviate from the target range, the APC unit 300 may make automatic adjustments such that the process parameters in the process chamber 35 reaches the target range.

In operation 3-13, the semiconductor device 30 may be picked from the load port 31 and be transferred to the load lock 33. In some embodiments of the present disclosure, the atmospheric transfer module (ATM) 37 of the semiconductor manufacturing tool 3 may pick the semiconductor device 30 from the load port 21 and transfers the semiconductor device 30 to the load lock 33.

In operation 3-14, during the movement of the semiconductor device 30, the program 301 in the semiconductor manufacturing tool 3 may drive the semiconductor manufacturing tool 3 to provide the compensation for the process parameters in the process chamber 35. If, during or before this period, the process chamber 35 is left idle or undergoes other processes and thus the process parameters in the process chamber 35 may deviate from the target range, such compensation may cause the deviated process parameters to be close to the target range.

In operation 3-15, the semiconductor device 30 may be moved into the load lock 33 of the semiconductor manufacturing tool 3.

In operation 3-16, the semiconductor device 30 may be picked from the load lock 33 and be transferred to the process chamber 35. In some embodiments of the present disclosure, the vacuum transfer module (VTM) 39 of the semiconductor manufacturing tool 3 may pick the semiconductor device 30 from the load lock 23 and transfers the semiconductor device 30 to the process chamber 35.

In operation 3-17, the semiconductor device 30 may be moved into the process chamber 35 of the semiconductor manufacturing tool 3.

In operation 3-18, after the semiconductor device 30 is moved into the process chamber 35, the semiconductor manufacturing tool 3 may perform the semiconductor manufacturing process on the semiconductor device 30.

FIG. 4B is a flow chart representing a method 3-2 for operating the semiconductor manufacturing tool 3 in accordance with an embodiment of the present disclosure.

In operation 3-21, the semiconductor device 30 may be placed at the load port 31 of the semiconductor manufacturing tool 3. In some embodiments of the present disclosure, the semiconductor device 30 may be transferred from automated material handling systems, such as wafer handling robots.

In operation 3-22, the APC unit 300 may be triggered to monitor the process parameters in the process chamber 35. If the APC unit 300 detects that the process parameters in the process chamber 35 deviate from the target range, the APC unit 300 may make automatic adjustments such that the process parameters in the process chamber 35 reaches the target range.

In operation 3-23, the semiconductor device 30 may be picked from the load port 31 and be transferred to the load lock 33. In some embodiments of the present disclosure, the atmospheric transfer module (ATM) 37 of the semiconductor manufacturing tool 3 may pick the semiconductor device 30 from the load port 21 and transfers the semiconductor device 30 to the load lock 33.

In operation 3-24, the semiconductor device 30 may be moved into the load lock 33 of the semiconductor manufacturing tool 3.

In operation 3-25, after moving the semiconductor device 30 into the load lock 32, the program 301 in the semiconductor manufacturing tool 3 may drive the semiconductor manufacturing tool 3 to provide the compensation for the process parameters in the process chamber 35. If, during or before this period, the process chamber 35 is left idle or undergoes other processes and thus the process parameters in the process chamber 35 may deviate from the target range, such compensation may cause the deviated process parameters to be close to the target range.

In operation 3-26, the semiconductor device 30 may be picked from the load lock 33 and be transferred to the process chamber 35. In some embodiments of the present disclosure, the vacuum transfer module (VTM) 39 of the semiconductor manufacturing tool 3 may pick the semiconductor device 30 from the load lock 23 and transfers the semiconductor device 30 to the process chamber 35.

In operation 3-27, the semiconductor device 30 may be moved into the process chamber 35 of the semiconductor manufacturing tool 3.

In operation 3-28, after the semiconductor device 30 is moved into the process chamber 35, the semiconductor manufacturing tool 3 may perform the semiconductor manufacturing process on the semiconductor device 30.

FIG. 4C is a flow chart representing a method 3-3 for operating the semiconductor manufacturing tool 3 in accordance with an embodiment of the present disclosure.

In operation 3-31, the semiconductor device 30 may be placed at the load port 31 of the semiconductor manufacturing tool 3. In some embodiments of the present disclosure, the semiconductor device 30 may be transferred from automated material handling systems, such as wafer handling robots.

In operation 3-32, the APC unit 300 may be triggered to monitor the process parameters in the process chamber 35. If the APC unit 300 detects that the process parameters in the process chamber 35 deviate from the target range, the APC unit 300 may make automatic adjustments such that the process parameters in the process chamber 35 reaches the target range.

In operation 3-33, the semiconductor device 30 may be picked from the load port 31 and be transferred to the load lock 33. In some embodiments of the present disclosure, the atmospheric transfer module (ATM) 37 of the semiconductor manufacturing tool 3 may pick the semiconductor device 30 from the load port 21 and transfers the semiconductor device 30 to the load lock 33.

In operation 3-34, the semiconductor device 30 may be moved into the load lock 33 of the semiconductor manufacturing tool 3.

In operation 3-35, the semiconductor device 30 may be picked from the load lock 33 and be transferred to the process chamber 35. In some embodiments of the present disclosure, the vacuum transfer module (VTM) 39 of the semiconductor manufacturing tool 3 may pick the semiconductor device 30 from the load lock 23 and transfers the semiconductor device 30 to the process chamber 35.

In operation 3-36, during the movement of the semiconductor device 30, the program 301 in the semiconductor manufacturing tool 3 may drive the semiconductor manufacturing tool 3 to provide the compensation for the process parameters in the process chamber 35. If, during or before this period, the process chamber 35 is left idle or undergoes other processes and thus the process parameters in the process chamber 35 may deviate from the target range, such compensation may cause the deviated process parameters to be close to the target range.

In operation 3-37, the semiconductor device 30 may be moved into the process chamber 35 of the semiconductor manufacturing tool 3.

In operation 3-38, after the semiconductor device 30 is moved into the process chamber 35, the semiconductor manufacturing tool 3 may perform the semiconductor manufacturing process on the semiconductor device 30.

FIG. 4D is a flow chart representing a method 3-4 for operating the semiconductor manufacturing tool 3 in accordance with an embodiment of the present disclosure.

In operation 3-41, the semiconductor device 30 may be placed at the load port 31 of the semiconductor manufacturing tool 3. In some embodiments of the present disclosure, the semiconductor device 30 may be transferred from automated material handling systems, such as wafer handling robots.

In operation 3-42, the APC unit 300 may be triggered to monitor the process parameters in the process chamber 35. If the APC unit 300 detects that the process parameters in the process chamber 35 deviate from the target range, the APC unit 300 may make automatic adjustments such that the process parameters in the process chamber 35 reaches the target range.

In operation 3-43, the semiconductor device 30 may be picked from the load port 31 and be transferred to the load lock 33. In some embodiments of the present disclosure, the atmospheric transfer module (ATM) 37 of the semiconductor manufacturing tool 3 may pick the semiconductor device 30 from the load port 21 and transfers the semiconductor device 30 to the load lock 33.

In operation 3-44, the semiconductor device 30 may be moved into the load lock 33 of the semiconductor manufacturing tool 3.

In operation 3-45, the semiconductor device 30 may be picked from the load lock 33 and be transferred to the process chamber 35. In some embodiments of the present disclosure, the vacuum transfer module (VTM) 39 of the semiconductor manufacturing tool 3 may pick the semiconductor device 30 from the load lock 23 and transfers the semiconductor device 30 to the process chamber 35.

In operation 3-46, the semiconductor device 30 may be moved into the process chamber 35 of the semiconductor manufacturing tool 3.

In operation 3-47, after transferring the semiconductor device 30 into the process chamber 35, the program 301 in the semiconductor manufacturing tool 3 may drive the semiconductor manufacturing tool 3 to provide the compensation for the process parameters in the process chamber 35. If, during or before this period, the process chamber 35 is left idle or undergoes other processes and thus the process parameters in the process chamber 35 may deviate from the target range, such compensation may cause the deviated process parameters to be close to the target range.

In operation 3-38, after the semiconductor device 30 is moved into the process chamber 35, the semiconductor manufacturing tool 3 may perform the semiconductor manufacturing process on the semiconductor device 30.

It will be further appreciated that the foregoing method may be used for manufacturing a semiconductor device. In this case, the APC unit can modify process parameters in the process chamber when it is not in use or when other processes, like dry clean seasoning, are being carried out inside the chamber. These modifications are necessary to prevent the process parameters from deviating from the desired range. By implementing this method, the occurrence of wafers that fail to meet manufacturing specifications can be greatly reduced. Additionally, the overall productivity can be significantly improved.

According to one embodiment of the present disclosure, a method for manufacturing a semiconductor device comprises: providing the semiconductor device to a load port of a manufacturing tool; detecting a process parameter in a process chamber of the manufacturing tool and control the process parameter to a target range, moving the semiconductor device away from the load port and transferring into the process chamber; and after moving the semiconductor device away from the load port, performing a compensation for the process parameter in the process chamber of the manufacturing tool.

According to another embodiment, method of operating a semiconductor manufacturing tool comprises: receiving a semiconductor device in a load port of the semiconductor manufacturing tool; detecting a process chamber of the semiconductor manufacturing tool and adjusting a process parameter in the process chamber to a target range, transferring the semiconductor device away from the load port and into the process chamber; and initiating a provision of a compensation for the process parameter so that the process parameter in the process chamber reaches or approaches the target range

According to one embodiment of the present disclosure, semiconductor manufacturing tool comprises a load port configured to receive a semiconductor device; a load lock configured to accommodate the semiconductor device; a process chamber configured to accommodate the semiconductor device and to performs a semiconductor process on the semiconductor device; an atmospheric transfer module (ATM) configured to move the semiconductor device from the load port to the load lock; and a vacuum transfer module (VTM) configured to move the semiconductor device from the load lock to the process chamber. An APC (advanced process control) unit is connected to the semiconductor manufacturing tool and configured to detect a process parameter in the process chamber and control the process parameter to a target range while the semiconductor device is received in the load port. Upon removal of the semiconductor device from the load port, the semiconductor manufacturing tool is configured to operatively provide a compensation for the process parameter in the process chamber so that the process parameter in the process chamber reaches or approaches the target range.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
providing the semiconductor device to a load port of a manufacturing tool;
detecting a first value of a process parameter in a process chamber of the manufacturing tool when the semiconductor device is over the load port of a manufacturing tool;
moving the semiconductor device away from the load port and transferring the semiconductor device from the load port into the process chamber; and
after moving the semiconductor device away from the load port, performing a compensation for the process parameter in the process chamber of the manufacturing tool.

2. The method of claim 1, wherein the compensation is performed while the semiconductor device is being moved from the load port to a load lock of the manufacturing tool.

3. The method of claim 1, wherein the compensation is performed when the semiconductor device is in a load lock of the manufacturing tool.

4. The method of claim 1, wherein the compensation is performed while the semiconductor device is being moved away from a load lock of the manufacturing tool to the process chamber.

5. The method of claim 1, wherein the compensation is performed after the semiconductor device is moved into the process chamber.

6. The method of claim 1, wherein the compensation is predetermined.

7. The method of claim 1, further comprising: detecting a second value of the process parameter in the process chamber of the manufacturing tool when the semiconductor device is moved away from the load port, the compensation is based on the detected first value of the process parameter and the detected second value of the process parameter.

8. A method of operating a semiconductor manufacturing tool, comprising:
receiving a semiconductor device in a load port of the semiconductor manufacturing tool;
detecting a process chamber of the semiconductor manufacturing tool and adjusting a process parameter in the process chamber to a target range,
transferring the semiconductor device away from the load port and into the process chamber; and
initiating a provision of a compensation for the process parameter so that the process parameter in the process chamber reaches or approaches the target range.

9. The method of claim 8, wherein the provision of the compensation is initiated while an atmospheric transfer module (ATM) of the semiconductor manufacturing tool moves the semiconductor device.

10. The method of claim 8, wherein the provision of the compensation is initiated while a vacuum transfer module (VTM) of the semiconductor manufacturing tool moves the semiconductor device.

11. The method of claim 8, wherein the provision of the compensation is initiated when the semiconductor device is in a load lock of the semiconductor manufacturing tool.

12. The method of claim 8, wherein the provision of the compensation is initiated when the semiconductor device is in the process chamber.

13. The method of claim 8, wherein the provision of the compensation is programmable.

14. The method of claim 13, wherein the compensation is predetermined.

15. The method of claim 8, further comprising: monitoring the process chamber of the semiconductor manufacturing tool after transferring the semiconductor device away from the load port and before initiating the provision of the compensation for the process parameter.

16. The method of claim 15, wherein the provision of the compensation is controlled by an APC (advanced process control) unit which is connected to the semiconductor manufacturing tool.

17. A semiconductor manufacturing tool, comprising:
a load port configured to receive a semiconductor device;
a load lock configured to accommodate the semiconductor device;
a process chamber configured to accommodate the semiconductor device and to performs a semiconductor process on the semiconductor device;
an atmospheric transfer module (ATM) configured to move the semiconductor device from the load port to the load lock; and
a vacuum transfer module (VTM) configured to move the semiconductor device from the load lock to the process chamber;
wherein an APC (advanced process control) unit is connected to the semiconductor manufacturing tool and configured to detect a process parameter in the process chamber and control the process parameter to a target range while the semiconductor device is received in the load port;
wherein, upon removal of the semiconductor device from the load port, the semiconductor manufacturing tool is configured to operatively provide a compensation for the process parameter in the process chamber so that the process parameter in the process chamber reaches or approaches the target range.

18. The semiconductor manufacturing tool of claim 17, wherein the compensation is provided in one of following states:
a state in which the semiconductor device is moved by the atmospheric transfer module;
a state in which the semiconductor device is accommodated in the load lock;
a state in which the semiconductor device is moved by the vacuum transfer module; and
a state in which the semiconductor device is accommodated in the process chamber.

19. The semiconductor manufacturing tool of claim 17, wherein the semiconductor manufacturing comprises a program configured to provide the compensation.

20. The semiconductor manufacturing tool of claim 17, wherein the APC unit is configured to perform a detection on the process chamber after the semiconductor device is moved away from the load port and before the compensation is provided and to control a provision of the compensation based on the detection.
